(19) United States
(12) Patent Application Publication
(10) Pub. No.: US 2016/0308495 A1
(43) Pub. Date: Oct. 20, 2016

(54) WIDEBAND DOHERTY AMPLIFIER CIRCUIT WITH INTEGRATED TRANSFORMER LINE BALUN

(71) Applicant: Infineon Technologies AG, Neubiberg (DE)

(72) Inventors: Tim Canning, Regensburg (DE); Christian Schuberth, Villach-Landskron (AT); David Seebacher, Villach (AT)

(21) Appl. No.: 14/689,662

(22) Filed: Apr. 17, 2015

(51) Int. Cl. H03F 1/02; H03F 3/21; H03F 3/19

(52) U.S. Cl. CPC H03F 1/0288; H03F 3/19; H03F 3/211; H03F 2200/451; H03F 2203/21106

(57) ABSTRACT

A Doherty amplifier circuit includes an RF input terminal, an RF output terminal, a main amplifier having a first input terminal and a first output driving terminal, and a peaking amplifier having a second input terminal and a second output driving terminal. An output combining network is configured to feed output current from the first and second output driving terminals into a summing node. The output combining network includes a transmission line transformer balun having first and second input ports and a first output port being connected to the summing node, a first electrical connection between the first output driving terminal and the first input port, and a second electrical connection between the second output driving terminal and the second input port. The second electrical connection includes a quarter wave impedance inverter. A first output impedance matching network is connected between the summing node and the RF output terminal.

### TECHNICAL FIELD

The present application relates to Doherty amplifiers, in particular series connected Doherty amplifiers with summing networks that present a stable impedance transformation to the amplifier circuits over a wide bandwidth.

### BACKGROUND

RF (radio frequency) power architectures within the telecommunications field focus on achieving high DC-to-RF efficiency at significant power back off from Psat (the average output power when the amplifier is driven deep into saturation). This is due to the high peak to average ratio (PAR) of the transmitted digital signals such as W-CDMA (wideband code division multiple access), LTE (long term evolution) and WiMAX (worldwide interoperability for microwave access). The most popular power amplifier architecture currently employed is the Doherty amplifier. The Doherty amplifier employs a class AB main amplifier and a class C peaking amplifier, and efficiency is enhanced through load modulation of the main amplifier from the peaking amplifier.

Doherty amplifier circuits typically achieve peak efficiency only at a very limited bandwidth. One solution for improving the bandwidth limitation of Doherty amplifiers is to provide multiple amplifiers for different frequency bands. However, this solution increases system cost and complexity. Alternatively, multiple smaller and wider bandwidth amplifiers can be combined in parallel to achieve a suitable bandwidth. This scheme introduces additional combiner loss, requires additional circuit area for the combiner, and is therefore more costly and less power efficient.

### SUMMARY

A Doherty amplifier circuit is disclosed. According to an embodiment, the Doherty amplifier circuit includes an RF input terminal, an RF output terminal, a main amplifier having a first input terminal and a first output driving terminal, the first input terminal being connected to the RF input terminal, and a peaking amplifier having a second input terminal and a second output driving terminal, the second input terminal being connected to the RF input terminal. The Doherty amplifier circuit further includes an output combining network being configured to feed output current from the first and second output driving terminals into a summing node. The output combining network includes a transmission line transformer balun having first and second input ports and a first output port connected to the summing node, a first electrical connection between the first output driving terminal and the first input port, and a second electrical connection between the second output driving terminal and the second input port. The second electrical connection includes a quarter wave impedance inverter. The Doherty amplifier circuit further includes a first output impedance matching network connected between the summing node and the RF output terminal.

A packaged Doherty amplifier is disclosed. According to an embodiment, the packaged Doherty amplifier includes an electrically conductive RF input terminal, an electrically conductive RF output input terminal, a main amplifier including a first input terminal and a first output driving terminal, the first input terminal being connected to the RF input terminal, and the first output driving terminal opposite from the substrate, and a peaking amplifier including a second input terminal and a second output driving terminal, the second input terminal being connected to the RF input terminal, and the second output driving terminal opposite from the substrate. The packaged Doherty amplifier further includes an output combining network being configured to feed output current from the first and second output driving terminals into a summing node. The output combining network includes a transmission line transformer balun that is mounted on the substrate and includes first and second input ports and a first output port connected to the summing node, a first electrical connection between the first output driving terminal and the first input port, and a second electrical connection between the second output driving terminal and the second input port. The second electrical connection includes a quarter wave impedance inverter. The packaged Doherty amplifier further includes a first output impedance matching network connected between the summing node and the RF output terminal.

A method of operating a Doherty amplifier circuit having an RF input terminal, an RF output terminal, a main amplifier having a first input terminal and a first output driving terminal, the first input terminal being connected to the RF input terminal, and a peaking amplifier comprising a second input terminal and a second output driving terminal, the second input terminal being connected to the RF input terminal is disclosed. According to the method, an RF signal is amplified between RF input terminal and an RF output terminal using one or both of the main and peaking amplifiers. The amplified RF signal generated at the first and second output driving terminals is combined into a summing node using a transmission line transformer balun. An impedance between the second output driving terminal and the transmission line transformer balun is inverted using a quarter wave impedance inverter.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a series connected Doherty amplifier circuit with a transmission line transformer balun and a quarter wave impedance inverter connected to the summing node, according to an embodiment.

FIG. 2 illustrates an equivalent circuit of a series connected Doherty amplifier circuit that includes a transmission line transformer balun and is operating at full power mode, according to an embodiment.

FIG. 3 illustrates an equivalent circuit of a series connected Doherty amplifier circuit that includes a transmission line transformer balun and is operating at low power mode, according to an embodiment.

FIG. 4 illustrates an equivalent circuit of a series connected Doherty amplifier circuit that includes a transmission line transformer balun and a quarter wave impedance inverter and is operating an low power mode, according to an embodiment.

FIG. 5, which includes FIGS. 5A and 5B, illustrates a high level schematic diagram for a parallel connected Doherty amplifier circuit and a series connected Doherty amplifier circuit that includes a transmission line transformer balun, according to an embodiment.

FIG. 6, which includes FIGS. 6A and 6B, illustrates an impedance response of a parallel connected Doherty amplifier circuit and a series connected Doherty amplifier circuit that includes a transmission line transformer balun, according to an embodiment.

FIG. 7, which includes FIGS. 7A and 7B, compares the impedance response of a parallel connected Doherty amplifier circuit and a series connected Doherty amplifier circuit that includes a transmission line transformer balun at two different operating frequencies, according to an embodiment.

FIG. 8 depicts a packaged Doherty amplifier circuit, according to an embodiment.

### DETAILED DESCRIPTION

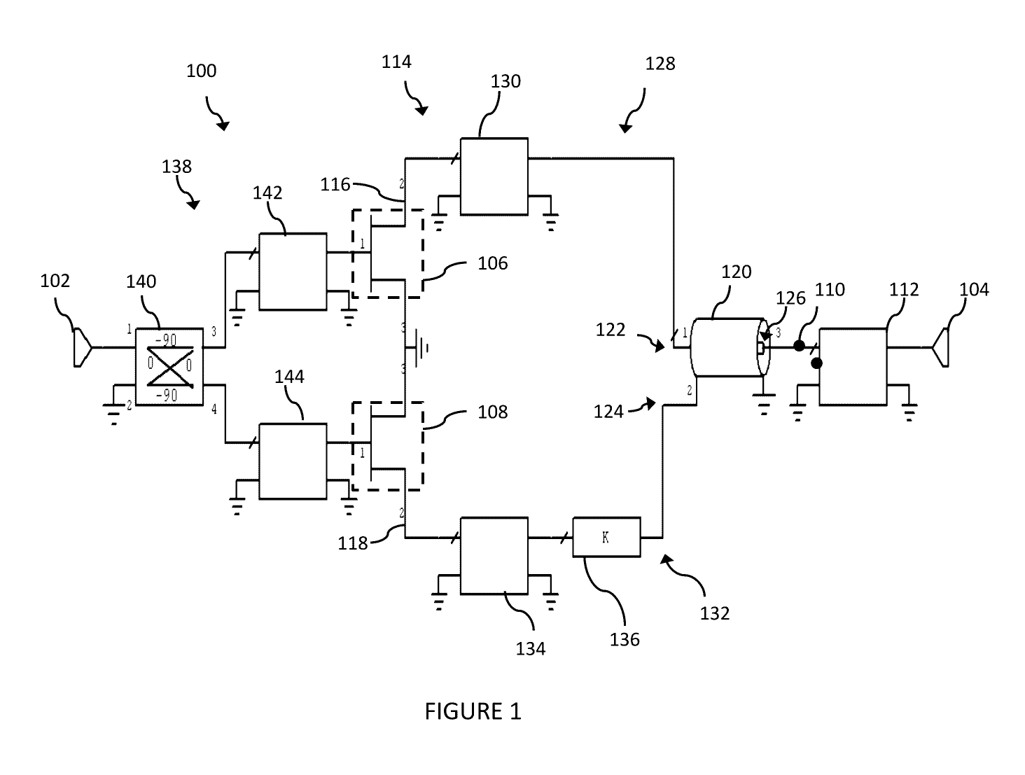

FIG. 1 illustrates a Doherty amplifier circuit 100. The Doherty amplifier circuit 100 includes at least one RF input terminal 102 and at least one RF output terminal 104. The Doherty amplifier circuit 100 is configured to amplify an RF signal as between the RF input terminal 102 and the RF output terminal 104 using a main amplifier 106 and a peaking amplifier 108. Both the main amplifier 106 and the peaking amplifier 108 are independently connected to the RF input terminal 102. That is, the signal applied to the RF input terminal 102 is fed into two discrete paths, with each path feeding an input terminal of the main amplifier 106 and an input terminal of the peaking amplifier 108, respectively. According to another embodiment, the Doherty amplifier circuit 100 includes two or more of the RF input terminals 102, with each of the RF input terminals 102 independently feeding the input terminals of the main amplifier 106 and the peaking amplifier 108.

The Doherty amplifier circuit 100 is configured to operate in a low power mode and in a high power mode. At lower power mode, only the main amplifier 106 is operational. The efficiency of the main amplifier 106 increases as the power level increases. The main amplifier 106 eventually reaches a maximum efficiency point as the power level continues to rise. At this power level, the peaking amplifier 108 turns on. In a high power mode, both the main main amplifier 106 and the peaking amplifier 108 are operational.

The Doherty amplifier circuit 100 of FIG. 1 is configured as a series connected Doherty amplifier. In such a configuration, the current delivered by the main amplifier 106 and the peaking amplifier 108 is combined at a summing node 110. The Doherty amplifier circuit 100 optionally includes a final impedance matching network 112, which is in series with the external load that the Doherty amplifier circuit 100 drives. According to an embodiment, the final impedance matching network 112 is configured as an LC or RLC network. The impedance of the final impedance matching network 112 may be matched to a standard external load impedance (e.g., 50Ω) for optimum efficiency.

The Doherty amplifier circuit 100 includes an output combining network 114 that is configured to feed output current from a first output driving terminal 116 of the main amplifier 106 and from a second output driving terminal 118 of the peaking amplifier 108 into the summing node 110. That is, the output combining network 114 combines the power generated by the main amplifier 106 and the peaking amplifier 108 at the summing node 110.

The output combining network 114 includes a transmission line transformer balun 120. The transmission line transformer balun 120 includes at least two conductors configured to carry an RF signal with minimal reflections (i.e., transmission lines), wherein the two conductors are designed to a multiple of a quarter wavelength of a center design frequency, and are coupled to form a transmission line between them. The balun includes first and second (unbalanced) input ports 122, 124 and a first (balanced) output port 126. The first output port 126 is connected to the to the summing node 110.

The output combining network 114 further includes a first electrical connection 128 between the first output driving terminal 116 and the first input port 122. The first electrical connection 128 may be effectuated using (nominally) perfectly conductive wire connections directly connecting the first output driving terminal 116 and the first input port 122. Alternatively, the Doherty amplifier circuit 100 may include a second output impedance matching network 130 connected to first output driving terminal 116 and the first input port 122. The second output impedance matching network 130 may include an LC or RLC network.

The output combining network 114 further includes a second electrical connection 132, which is discrete from the first electrical connection 128, and is between the second output driving terminal 118 and the second input port 124. The second electrical connection 132 may be effectuated using (nominally) perfectly conductive wire connections directly connecting the second output driving terminal 118 and the second input port 124. Alternatively, the Doherty amplifier circuit 100 may include a third output impedance matching network 134 connected to second output driving terminal 118 and the second input port 124. The third output impedance matching network 134 may include an LC or RLC network.

The second electrical connection 132 includes a quarter wave impedance inverter 136. That is, current flowing between the second output driving terminal 118 and the second input port 124 must pass through the quarter wave impedance inverter 136. According to an embodiment, the second output impedance matching network 134 is directly connected to the quarter wave impedance inverter 136, and the quarter wave impedance inverter 136 is directly electrically connected to the second input port 124 of the transmission line transformer balun 120. The impedance inverter 136 and the output matching network 134 may be implemented separately, or combined into a single network.

The quarter wave impedance inverter 136 is a two port network configured to present the dual or reciprocal impedance with which it is terminated. Thus, a very high impedance at one end of the quarter wave impedance inverter 136 will appear as a very low impedance at the other end and vice-versa. The quarter wave impedance inverter 136 may have any of a variety of commonly known configurations. For example, the quarter wave impedance inverter 136 may be configured as a single length of transmission line or alternatively may be implemented as a network of lumped elements.

In the embodiment depicted in FIG. 1, the Doherty amplifier circuit 100 additionally includes an input network 138 connected between the RF input terminal 102 and the input terminals of the main amplifier 106 and the peaking amplifier 108. The input network 138 includes a ninety degree hybrid coupler 140 that is electrically connected to the RF input terminal 102. The ninety degree hybrid coupler 140 splits the RF signal into two signals with a 90 degree phase shift between them. These phase shifted signals are fed from two output ports of the ninety degree hybrid coupler 140 to the input terminals 116, 118 of the main and peaking amplifiers 106, 108. According to an embodiment, a first input impedance matching network 142 is connected between a first output terminal of the ninety degree hybrid coupler 140 and an input terminal of the main amplifier 106, and a second input impedance matching network 144 is connected between a second output terminal of the ninety degree hybrid coupler 140 and an input terminal of the peaking amplifier 108. According to another embodiment, the ninety degree hybrid coupler 140 is not part of the input network 138, and may be provided externally.

According to an embodiment, the main amplifier 106 and peaking amplifier 108 are each configured as three terminal power transistors having gate, source and drain terminals. The drain terminal of the main amplifier 106 provides the first output driving terminal 116 and the drain terminal of the peaking amplifier 108 provides the second output driving terminal 118. The source terminals of the main and peaking amplifiers 106, 108 are connected to one another and to a reference (i.e., ground). This is only one example, and the main amplifier 106 and peaking amplifier 108 can be provided by any of a variety of device types, such a power MOSFET, IGBT, BJT, thyristor, etc.

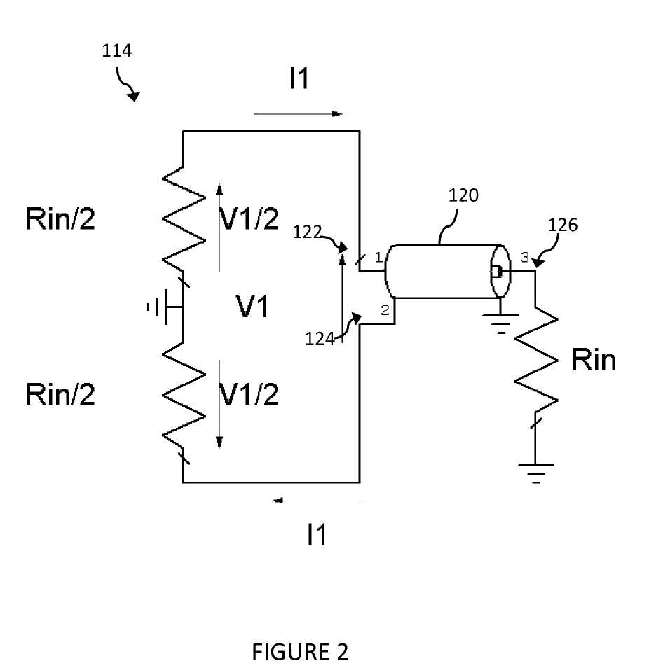

The load modulation characteristics of the output combining network 114 will now be discussed. Referring to FIG. 2, an equivalent input impedance model of the Doherty amplifier circuit 100 is depicted with the Doherty amplifier operating in full power mode (i.e., with both the main amplifier 106 and peaking amplifier 108 driving the output). The transmission line transformer balun 120 is nominally configured to balance electrical current as between first and second input ports 122, 124. Therefore, the current flowing into the first input port 122 is equal in magnitude and opposite in phase to the current flowing out of the second input port 124. Furthermore, the voltage between the first and second input ports 122, 124 must be equal to the voltage at the output port 126. One half of the of the voltage difference between the first and second input ports 122, 124 is across the main amplifier 106 and one half of the of the voltage difference between the first and second input ports 122, 124 is across the peaking amplifier 108. Thus, both the main amplifier 106 and the peaking amplifier 108 see an input resistance (Rᵢₙ) equal to Rᵢₙ/2. Thus, the transmission line transformer balun 120 provides a 2:1 impedance transformation.

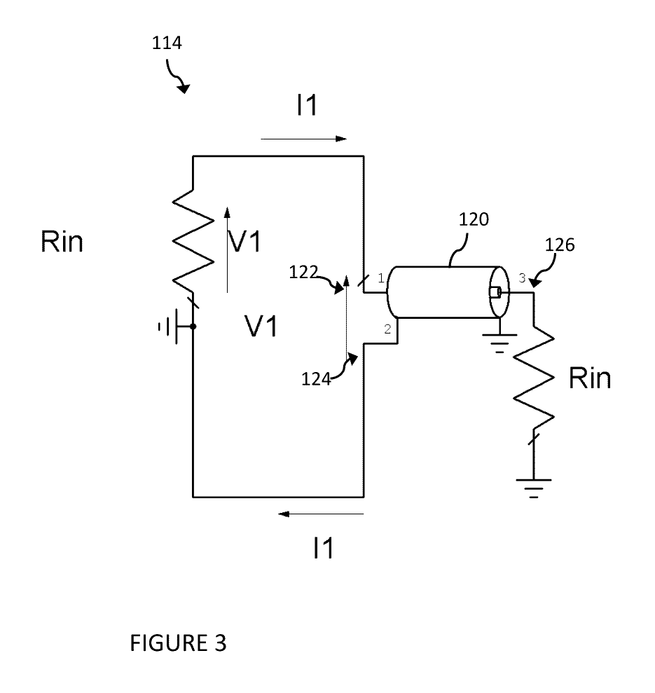

FIG. 3 depicts an equivalent input impedance model of the Doherty amplifier circuit 100 with the Doherty amplifier operating in low power mode (i.e., only the main amplifier 106 operational and the peaking amplifier 108 is completely turned off). In this circuit, the peaking amplifier 108 appears as a short from the perspective of the second input port 124. By making the peaking amplifier 108 appear as a short, the load seen by the main amplifier 106 will be doubled because all of the voltage difference between the first and second input ports 122, 124 is across the main amplifier 106. Thus, the output combining network 114 optimizes the power efficiency of the Doherty amplifier circuit 100 in either of the high power or low power modes by matching the input resistance seen by the main amplifier 106 main and peaking amplifiers 108 to an Rᵢₙ value that is set by the impedance that is connected to the summing node 126, and by modulating the impedance seen by the main amplifier 106 or the peaking amplifier 108 dependent upon the power mode.

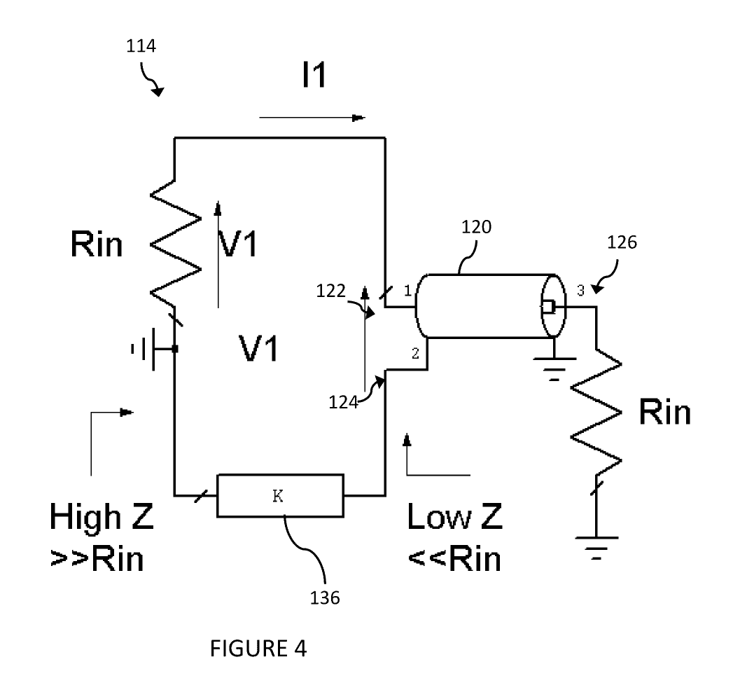

FIG. 4 depicts the incorporation of the quarter wave impedance inverter 136 into the output combining network 114 to make the peaking amplifier 108 appear as a short when the Doherty amplifier circuit 100 is in low power mode. In the case that the peaking amplifier 108 is turned off, it presents a very high impedance. That is, the peaking amplifier 108 nominally appears as an open when it is turned off. The quarter wave impedance inverter 136 presents the dual or inverse of this open circuit, which is a short circuit, from the perspective of the second input port 124.

The impedance inversion provided by the quarter wave impedance inverter 136 is centered to a particular frequency, as it requires a transmission line length that is equal to exactly one-quarter of a wavelength (λ) long of the transmitted frequency. Thus, the quarter wave impedance inverter 136 is only able to function as in ideal inverter at a single frequency.

The incorporation of a transmission line transformer balun 120 into the output combining network 114 in the manner described herein advantageously presents a highly stable impedance versus frequency to the quarter wave impedance inverter 136. The balun 120 additionally operates as a dual mode 2:1 impedance inverter (i.e., 50 ohms at the output port 126 of the balun 120 is converted to 25 ohms at the main and peaking amplifiers 106, 108), combined with a very compact wideband power combiner, which reduces the amount of impedance transformation which must be performed elsewhere in the circuit. This also enhances bandwidth, as the balun 120 is able to provide the 2:1 impedance transformation over a wider bandwidth, with equivalent or lower loss, than conventional techniques that utilize LC filter matching networks after the summing node 110.

The transmission line transformer balun 120 naturally presents a high impedance to the second harmonic at the balanced ports 122, 124. This is due to the property of the balanced structure to reject even mode current, which is active when the peaking amplifier 108 is fully operational. This property can be used to maximize the efficiency of both the main and peaking amplifiers 106, 108 through the power range, whereby friendly passive and even active impedances can be presented to the individual transistors, maximizing efficiency.

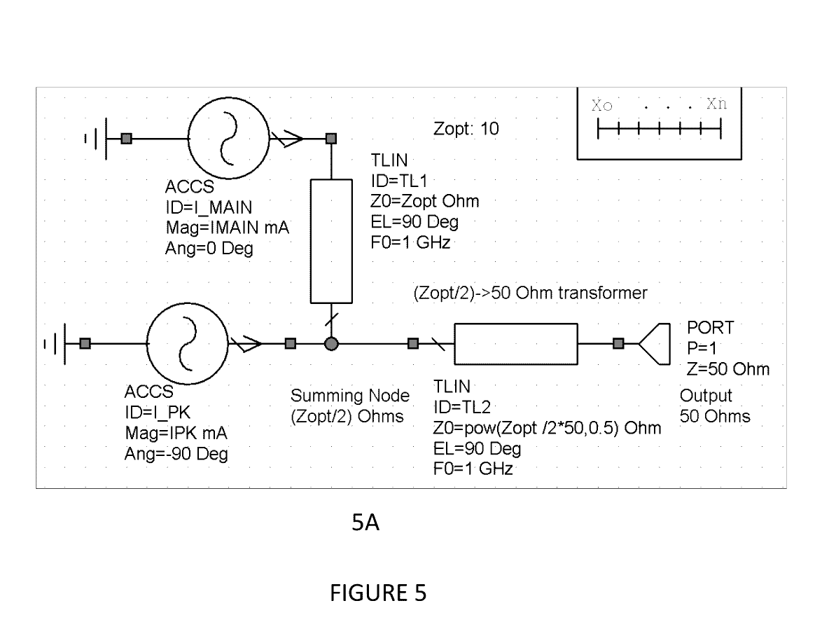

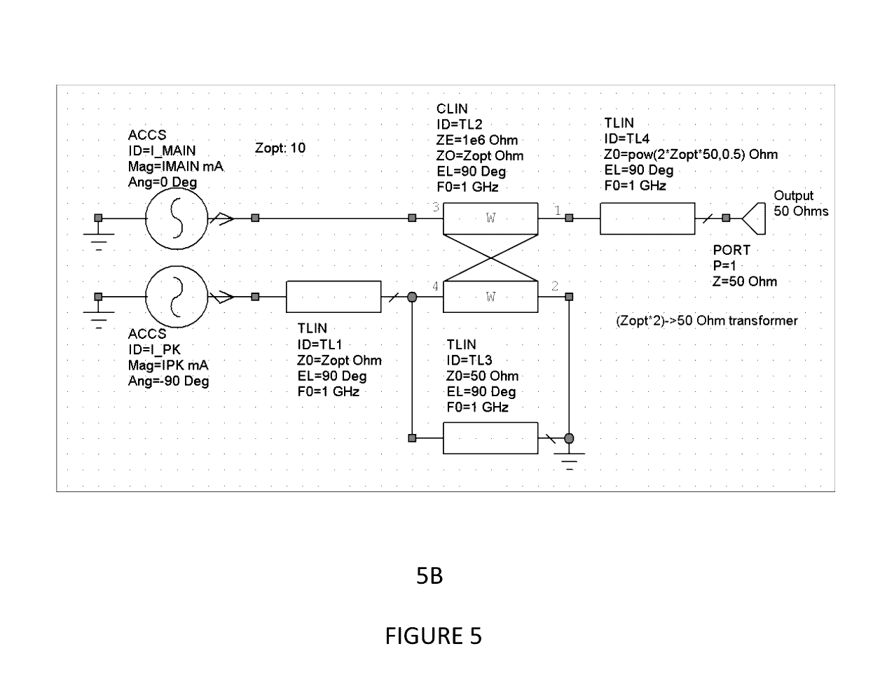

An example of the beneficial impedance versus frequency characteristic of the output combining network 114 that includes the transmission line transformer balun 120 will now be discussed. Referring to FIG. 5, a high level schematic diagram for two different Doherty circuits is depicted. FIG. 5A depicts a conventionally configured Doherty amplifier with a parallel summing node. FIG. 5B depicts a series connected Doherty amplifier with the transmission line transformer balun 120 being configured in the output combining network 114 described herein. The summing node impedance in the circuit of FIG. 5A is equal to Z_{OPT}/2Ω and the summing node impedance in the circuit of FIG. 5B is equal to Z_{OPT}*2Ω, where Z_{OPT} is the impedance presented to the main amplifier 106 and the peaking amplifier 108 in full power mode.

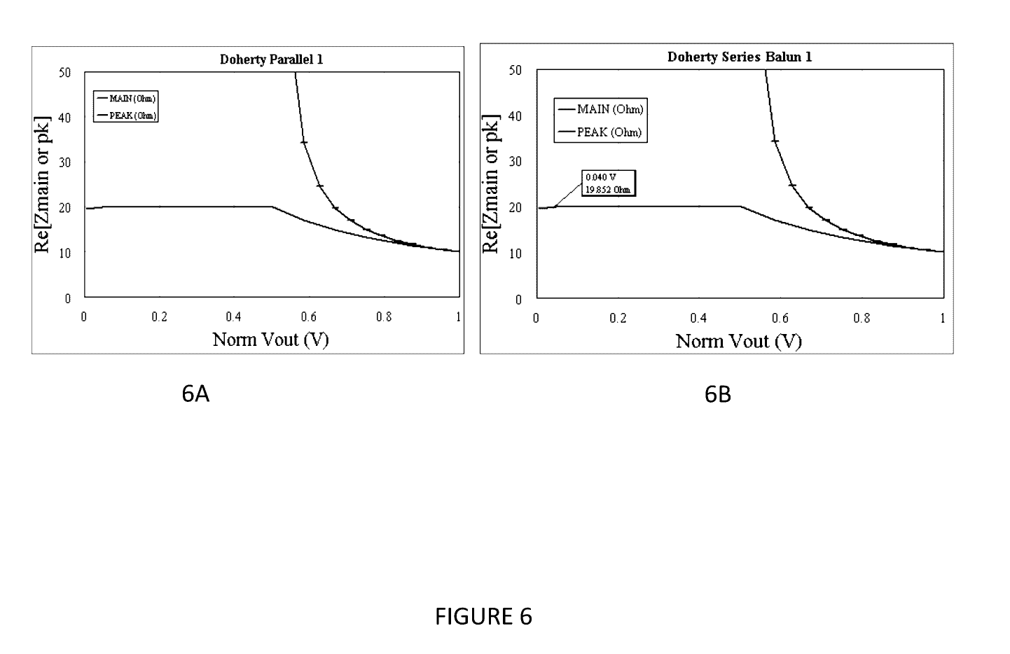

FIG. 6 depicts the impedance presented to the main amplifier 106 and the peaking amplifiers 108, with the Doherty amplifier being operated at 1 GHz. FIG. 6A depicts the impedance presented to the parallel summing Doherty amplifier (i.e., the circuit of FIG. 5A) and FIG. 6B depicts the impedance presented to the series connected Doherty amplifier with a transmission line transformer balun 120 (i.e., the circuit of FIG. 5B). The far left of both of the graphs represents the low power mode in which only the main amplifier 106 is operational and the far right of the graph represents full power mode in which both the main amplifier 106 and the peaking amplifier 108 are driving an equal amount of current. At low power mode, the main amplifier 106 sees approximately 20Ω. At full power mode, the impedance presented to both the main amplifier 106 and the peaking amplifier 108 (i.e., Z_{OPT}) is 10Ω.

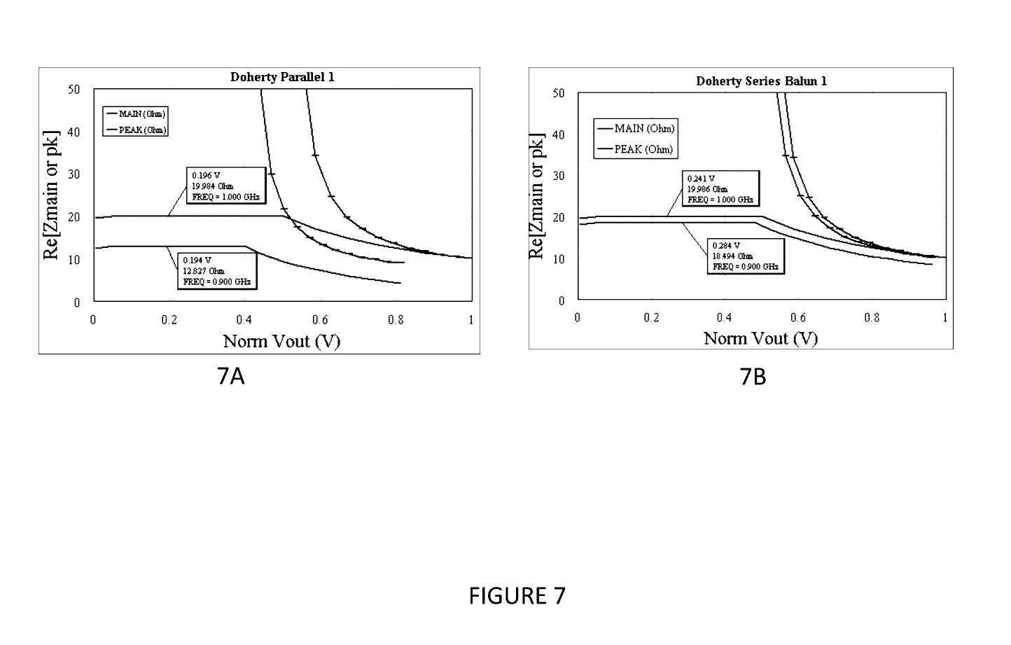

FIG. 7 illustrates a frequency comparison of the impedance characteristics shown in FIG. 6. FIG. 7A depicts the parameters of the parallel summing Doherty amplifier (i.e., the circuit of FIG. 5A) and FIG. 7B depicts the parameters of the series connected Doherty amplifier with a transmission line transformer balun 120 (i.e., the circuit of FIG. 5B). In both FIG. 7A and 7B, the uppermost curve depicts the impedance response with the Doherty amplifier being operated at 1 GHz and the lowermost curve depicts the impedance response with the Doherty amplifier being operated at 900 MHz. As can be seen, the series connected Doherty amplifier maintains the desired impedances much more effectively than the parallel connected Doherty amplifier. That is, the 100 MHz shift in operation frequency dramatically shifts the impedance presented to the main and peaking amplifiers 106, 108 downward for the parallel configuration. However, the 100 MHz shift in operation frequency has very little impact on the impedance presented to the main and peaking amplifiers 106, 108 such that Z_{OPT} remains at approximately 10Ω. Thus, the transmission line transformer balun 120 configuration described herein beneficially improves the wideband response of the Doherty amplifier circuit 100 in comparison to conventionally known summing techniques.

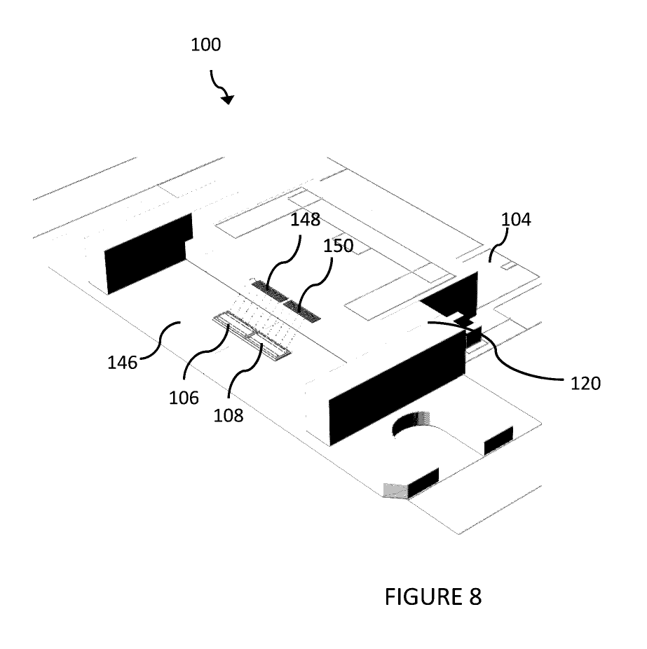

FIG. 8 depicts a packaged Doherty amplifier circuit 100, according to an embodiment. The Doherty amplifier circuit 100 has the circuit topology described with reference to FIG. 1. The main amplifier 106 and the peaking amplifier 108 may be mounted on an electrically conductive substrate 146. The main and peaking amplifiers 106, 108 may be configured in a so-called source down configuration, with the first and second output driving terminals 116, 118 facing away or opposite from the substrate 146.

The output combining network 114 described with reference to FIG. 1 has been integrated into the device package, with the transmission line transformer balun 120 mounted on the substrate 146. According to an embodiment, the transmission line transformer balun 120 and the main and peaking amplifers 106, 108 are each mounted on a continuous region of the substrate 146. The transmission line transformer balun 120 includes first and second bond pads 148, 150 being vertically offset from the substrate 146. The first electrical connection 128 may be effectuated using bonding wires connected between the first output driving terminal 116 and the first bond pad 148. The second electrical connection 132 may be effectuated using bonding wires connected between the second output driving terminal 118 and second bond pad 150.

Terms such as “same,” “match” and “matches” as used herein are intended to mean identical, nearly identical or approximately so that some reasonable amount of variation is contemplated without departing from the spirit of the invention. The term “constant” means not changing or varying, or changing or varying slightly again so that some reasonable amount of variation is contemplated without departing from the spirit of the invention. Further, terms such as “first,” “second,” and the like, are used to describe various elements, regions, sections, etc. and are also not intended to be limiting. Like terms refer to like elements throughout the description.

The term “directly electrically connected” or “in direct electrical contact” describes a permanent low-ohmic connection between electrically connected elements, for example a wire connection between the concerned elements. By contrast, the term “electrically coupled” means that one or more intervening element(s) configured to influence the electrical signal in some tangible way is be provided between the electrically coupled elements. These intervening elements include active elements, such as transistors, as well as passive elements, such as inductors, capacitors, diodes, resistors, etc.

As used herein, the terms “having,” “containing,” “including,” “comprising” and the like are open ended terms that indicate the presence of stated elements or features, but do not preclude additional elements or features. The articles “a,” “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A Doherty amplifier circuit, comprising:
an RF input terminal;
an RF output terminal;
a main amplifier comprising a first input terminal and a first output driving terminal, the first input terminal being connected to the RF input terminal;
a peaking amplifier comprising a second input terminal and a second output driving terminal, the second input terminal being connected to the RF input terminal; and
an output combining network being configured to feed output current from the first and second output driving terminals into a summing node, the output combining network comprising:
a transmission line transformer balun comprising first and second input ports and a first output port being connected to the summing node;
a first electrical connection between the first output driving terminal and the first input port; and
a second electrical connection between the second output driving terminal and the second input port, the second electrical connection comprising a quarter wave impedance inverter.

2. The Doherty amplifier circuit of claim 1, further comprising:
a second output impedance matching network connected to first output driving terminal and the first input port;
a third output impedance matching network connected to the second output driving terminal and the quarter wave impedance inverter;
a direct electrical connection between the second output impedance matching network and the second input port; and
a first output impedance matching network connected between the summing node and the RF output terminal.

3. The Doherty amplifier circuit of claim 2, further comprising:
a ninety degree hybrid coupler electrically connected to the input terminal;
a first input impedance matching network connected between a first output terminal of the ninety degree hybrid coupler and an input terminal of the main amplifier; and
a second input impedance matching network connected between a second output terminal of the ninety degree hybrid coupler and an input terminal of the peaking amplifier.

4. The Doherty amplifier circuit of claim 1, wherein the main amplifier and peaking amplifier are each configured as three terminal power transistors having gate, source and drain terminals, the source terminals of the main and peaking amplifiers being connected to a common ground node, the drain terminal of the main amplifier providing the first output driving terminal, and the drain terminal of the peaking amplifier providing the second output driving terminal.

6. The Doherty amplifier circuit of claim 1, wherein the main amplifier, the peaking amplifier, and the transmission line transformer balun are integrated into a single device package.

6. The Doherty amplifier circuit of claim 1, wherein the transmission line transformer balun is configured to present a 2:1 impedance transformation to the main and peaking amplifiers.

7. A packaged Doherty amplifier, comprising:
an electrically conductive RF input terminal;
an electrically conductive RF output input terminal;
a planar substrate;
a main amplifier comprising a first input terminal and a first output driving terminal, the first input terminal being connected to the RF input terminal, and the first output driving terminal opposite from the substrate;
a peaking amplifier comprising a second input terminal and a second output driving terminal, the second input terminal being connected to the RF input terminal, and the second output driving terminal opposite from the substrate; and
an output combining network being configured to feed output current from the first and second output driving terminals into a summing node, the output combining network comprising:
a transmission line transformer balun mounted on the substrate and comprising first and second input ports and a first output port being connected to the summing node;
a first electrical connection between the first output driving terminal and the first input port; and
a second electrical connection between the second output driving terminal and the second input port, the second electrical connection comprising a quarter wave impendence inverter.

8. The packaged Doherty amplifier of claim 7, wherein the main amplifier, the peaking amplifier, and the transmission line transformer balun are each mounted on an electrically conductive and continuous region of the substrate wherein the transmission line transformer balun comprises first and second bond pads being vertically offset from the substrate, wherein the first electrical connection comprises bonding wires connected between the first output driving terminal and the first bond pad, and wherein the second electrical connection comprises bonding wires connected between the second output driving terminal and the second bond pad.

9. The packaged Doherty amplifier of claim 8, wherein the substrate provides a source terminal of the packaged Doherty amplifier, wherein the main amplifier and peaking amplifier are each configured as three terminal power transistors having gate, source and drain terminals, wherein the main amplifier and peaking amplifier are mounted in a source down configuration.

10. The packaged Doherty amplifier of claim 7, wherein the transmission line transformer balun is configured to present a 2:1 impedance transformation to the main and peaking amplifiers.

11. The packaged Doherty amplifier of claim 7, further comprising:
a first output impedance matching network connected between the summing node and the RF output terminal.

12. A method of operating a Doherty amplifier circuit comprising an RF input terminal, an RF output terminal, a main amplifier comprising a first input terminal and a first output driving terminal, the first input terminal being connected to the RF input terminal, and a peaking amplifier comprising a second input terminal and a second output driving terminal, the second input terminal being connected to the RF input terminal, the method comprising:
amplifying an RF signal between RF input terminal and an RF output terminal using one or both of the main and peaking amplifiers;
combining the amplified RF signal generated at the first and second output driving terminals into a summing node using a transmission line transformer balun; and
inverting an impedance between the second output driving terminal and the transmission line transformer balun using a quarter wave impedance inverter.

13. The method of claim 12, wherein combining the amplified RF signal generated at the first and second output driving terminals into a summing node comprises feeding current from the first and second output driving terminals into first and second input ports of the transmission line transformer balun, and outputting the current at an unbalanced output port of the transmission line transformer balun, the unbalanced output port being directly connected to the summing node.

14. The method of claim 13, wherein amplifying the RF signal comprises operating only the main amplifier in a lower power mode and operating both of the main amplifier and the peaking amplifier in a high power mode, and wherein inverting the impedance comprises using the quarter wave impedance inverter to invert an impedance between the second input port and the second output driving terminal.

15. The method of claim 12, wherein the amplified RF signal generated at the first and second output driving terminals is combined using a balun that is integrated into the package structure of the Doherty amplifier circuit.
